(19) United States
(12) Patent Application Publication
(10) Pub. No.: US 2026/0305461 A1
(43) Pub. Date: Oct. 1, 2026

(54) METHOD FOR MANUFACTURING SEMICONDUCTOR DEVICE

(71) Applicant: Resonac Corporation, Minato-ku, Tokyo (JP)

(72) Inventors: Yoshiki MARUYAMA, Tokyo (JP); Kazuyuki MITSUKURA, Tokyo (JP); Tadashi OKUDA, Tokyo (JP); Shizu FUKUZUMI, Tokyo (JP); Yuta FUJITA, Tokyo (JP)

(21) Appl. No.: 19/478,830

(22) PCT Filed: Aug. 10, 2023
(86) PCT No.: PCT/JP2023/029343

§ 371 Date: Oct. 27, 2025

(51) Int. Cl. H10W 80/00; H10W 90/00; H10W 90/26; H10W 95/00

(52) U.S. Cl. CPC H10W 80/033; H10W 80/037; H10W 80/312; H10W 80/327; H10W 90/26; H10W 90/792; H10W 95/00

(57) ABSTRACT

In this method a substrate 10 is prepared that includes a support substrate 11, a conductive part 12, and a polyimide film 13 provided on the support substrate 11 and on the conductive part 12. The polyimide film 13 includes a first portion 13a covering a surface of the support substrate 11 and a side surface of the conductive part 12, and a second portion 13b positioned on the first portion 13a and covering a top surface of the conductive part 12. In this method, after cutting at least a part of the second portion 13b by a fly-cutting method while leaving the first portion 13a, a surface of the polyimide film 13 is polished. As a result, an operation time in the polishing is shortened, and the surface roughness of the substrate 10 can be easily reduced. The substrate 10 can be used for hybrid bonding.

### TECHNICAL FIELD

The present disclosure relates to a method for manufacturing a semiconductor device.

### BACKGROUND ART

In recent years, three-dimensional packaging has been studied to improve the degree of integration of LSIs. Non-Patent Literature 1 discloses an example of three-dimensional packaging of semiconductor chips.

### CITATION LIST

### Non Patent Literature

Non-Patent Literature 1: F.C. Chen et al., “System on Integrated Chips (SoIC™) for 3D Heterogeneous Integration”, 2019 IEEE 69th Electronic Components and Technology Conference (ECTC), p. 594-599 (2019)

### SUMMARY OF INVENTION

### Technical Problem

When manufacturing a semiconductor device by three-dimensional packaging, the use of hybrid bonding technology, which directly bonds devices to each other, is being considered for miniaturization of wiring between the devices. However, if a substrate surface of a device is rough, bonding failure may occur during hybrid bonding. Specifically, the greater a surface roughness of the substrate, the lower a bonding strength between the devices may be. Therefore, it has been considered to planarize the substrate surface and reduce the surface roughness by cutting the substrate surface by a fly-cutting method or by polishing the substrate surface. On the other hand, while cutting the substrate surface by the fly-cutting method alone allows for high-speed planarization, it is difficult to sufficiently reduce the surface roughness. Polishing the substrate surface alone can reduce the surface roughness, but there is a problem that the polishing operation is time-consuming. Therefore, a method for manufacturing a semiconductor device that can easily reduce surface roughness is desired.

### Solution to Problem

An object of the present disclosure is to provide a method for manufacturing a semiconductor device that can easily reduce surface roughness.

### Advantageous Effects of Invention

[1] As one aspect, the present disclosure relates to a method for manufacturing a semiconductor device. This method for manufacturing a semiconductor device includes: a preparing a substrate, the substrate including: a support substrate; a conductive part provided on the support substrate; and an insulating film provided on the support substrate and on the conductive part, wherein the insulating film includes: a first portion covering a surface of the support substrate and a side surface of the conductive part; and a second portion positioned on the first portion and covering a top surface of the conductive part; a cutting at least a portion of the second portion by a fly-cutting method while leaving the first portion; and a polishing a surface of the insulating film, wherein the polishing is performed after the cutting.

In this manufacturing method, after cutting at least the portion of the second portion covering the top surface of the conductive part by the fly-cutting method while leaving the first portion covering the surface of the support substrate and the side surface of the conductive part, the surface of the insulating film is polished. In this case, a part of the polishing can be replaced by the cutting. This makes it possible to reduce a surface roughness while shortening the processing time in the polishing. Therefore, according to the method for manufacturing a semiconductor device of [1], the surface roughness can be easily reduced.

[2] In the method for manufacturing a semiconductor device of [1], in the cutting, the second portion may be cut such that at least a part of the second portion remains. In the polishing, a remaining portion of the cut second portion may be polished such that a surface of the first portion and the top surface of the conductive part are flush with each other. When performing the above-mentioned planarization, the conductive part that will become an electrode may be elongated, and a shape of the conductive part may change. If the shape of the conductive part that will become an electrode changes, there is a risk of bonding failure during subsequent hybrid bonding. However, according to the method for manufacturing a semiconductor device of [2], the change in the shape of the conductive part can be suppressed, and bonding failure during subsequent hybrid bonding can be suppressed.

[3] In the method for manufacturing a semiconductor device of [1], in the cutting, the second portion may be cut such that a surface of the first portion and the top surface of the conductive part are flush with each other. In the polishing, the surface of the first portion is polished. In this case, it is possible to reduce the surface roughness while further shortening the operation time in the polishing. Therefore, according to the method for manufacturing a semiconductor device of [3], the surface roughness can be reduced even more easily.

[4] In the method for manufacturing a semiconductor device according to any one of [1] to [3], in the polishing, the surface of the cut insulating film may be polished by a CMP method. According to the method for manufacturing a semiconductor device of [4], the polishing can be performed easily. In addition, the surface roughness of the surface of the insulating film can be more reliably reduced.

[5] The method for manufacturing a semiconductor device according to any one of [1] to [4] may further include: a preparing a substrate, the substrate including: another support substrate; another conductive part provided on the another support substrate; and another insulating film provided on the another support substrate and on the another conductive part; and a bonding the substrate and the another substrate after the polishing. In this case, for the reasons described above, the substrate and the another substrate are bonded in a state where the surface roughness of the substrate is reduced. Therefore, according to the method for manufacturing a semiconductor device of [5], the bonding strength between the substrate and the another substrate can be improved.

### BRIEF DESCRIPTION OF DRAWINGS

FIG. 1 is a diagram showing an example of a semiconductor device manufactured by a method for manufacturing a semiconductor device according to an embodiment of the present disclosure.

FIG. 2 is a cross-sectional view for explaining the method for manufacturing a semiconductor device according to an embodiment of the present disclosure, showing an example of a step of preparing a substrate.

FIG. 3 is a cross-sectional view for explaining the method for manufacturing a semiconductor device according to an embodiment of the present disclosure, showing an example of a step of cutting a second portion of an insulating film by a fly-cutting method.

FIG. 4 is a cross-sectional view for explaining the method for manufacturing a semiconductor device according to an embodiment of the present disclosure, showing an example of a step of polishing a surface of the cut insulating film.

FIG. 5 is a cross-sectional view for explaining the method for manufacturing a semiconductor device according to an embodiment of the present disclosure, showing an example of a step of bonding a substrate and another substrate.

FIG. 6 is a cross-sectional view for explaining the method for manufacturing a semiconductor device according to an embodiment of the present disclosure, showing another example of a step of cutting a second portion of an insulating film by a fly-cutting method.

### DESCRIPTION OF EMBODIMENTS

Hereinafter, some embodiments of the present disclosure will be described in detail with reference to the drawings as necessary. In the following description, the same or corresponding parts are denoted by the same reference signs, and redundant description will be omitted. Positional relationships such as up, down, left, and right are based on the positional relationships shown in the drawings, unless otherwise specified. When terms such as “left,” “right,” “front,” “back,” “top,” “bottom,” “upper,” and “lower” are used in this specification and the claims, they are intended for explanation and do not necessarily mean that they are permanently in this relative position. Furthermore, the dimensional ratios in the drawings are not limited to the illustrated ratios. In this specification, the term “step” includes not only an independent step but also a case where the intended action of the step is achieved even if it cannot be clearly distinguished from other steps.

### (Configuration of Semiconductor Device)

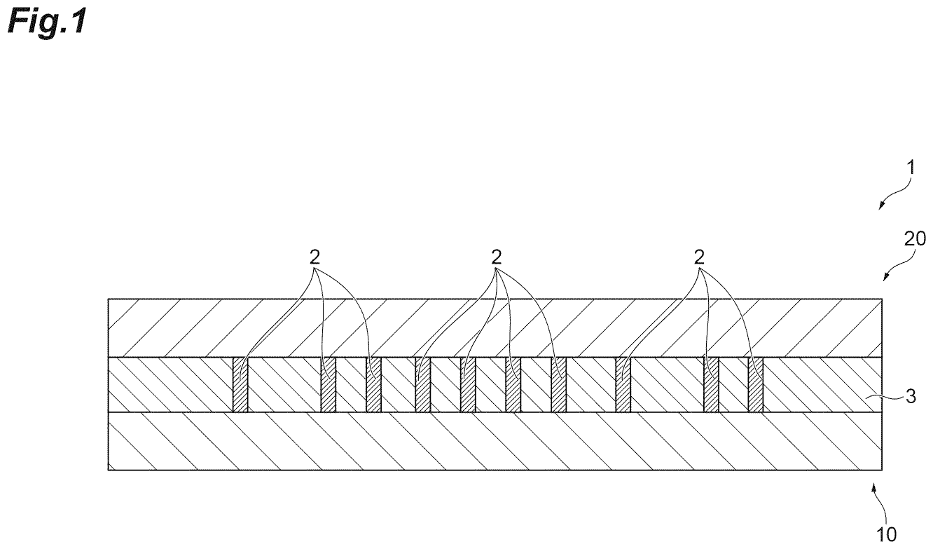

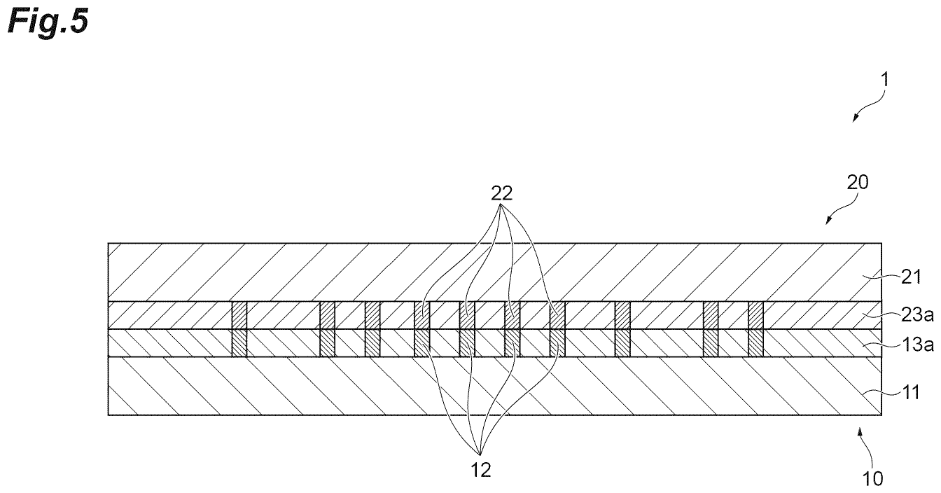

First, with reference to FIG. 1, the configuration of a semiconductor device 1 manufactured by the method for manufacturing a semiconductor device according to the present embodiment will be described. FIG. 1 shows an example of a semiconductor device manufactured by the method for manufacturing a semiconductor device according to the present embodiment. As shown in FIG. 1, the semiconductor device 1 is, for example, an example of a semiconductor package, and includes a plurality of electrodes 2, an insulating film 3, a substrate 10, and a substrate 20. The electrode 2 is formed by bonding a conductive part 12 of the substrate 10 and a conductive part 22 of the substrate 20, which will be described later (see FIG. 5). The insulating film 3 is formed by bonding an insulating film 13 (first portion 13a) of the substrate 10 and an insulating film 23 (first portion 23a) of the substrate 20, which will be described later (see FIG. 5). In the semiconductor device 1, the substrate 10 and the substrate 20 are bonded. The substrate 10 may include a semiconductor element. The semiconductor element included in the substrate 10 may be disposed on the surface opposite to the substrate 20 in a state where the substrate 10 and the substrate 20 are bonded. The substrate 20 may also include a semiconductor element. The semiconductor element included in the substrate 20 may be disposed on the surface opposite to the substrate 10 in a state where the substrate 10 and the substrate 20 are bonded. The semiconductor elements included in the substrate 10 and the substrate 20 are, for example, semiconductor chips such as LSI (Large Scale Integrated Circuit) chips, CMOS (Complementary Metal Oxide Semiconductor) sensors, or memories. The semiconductor elements included in the substrate 10 and the substrate 20 may be other types of semiconductor chips.

### (Method for Manufacturing Semiconductor Device)

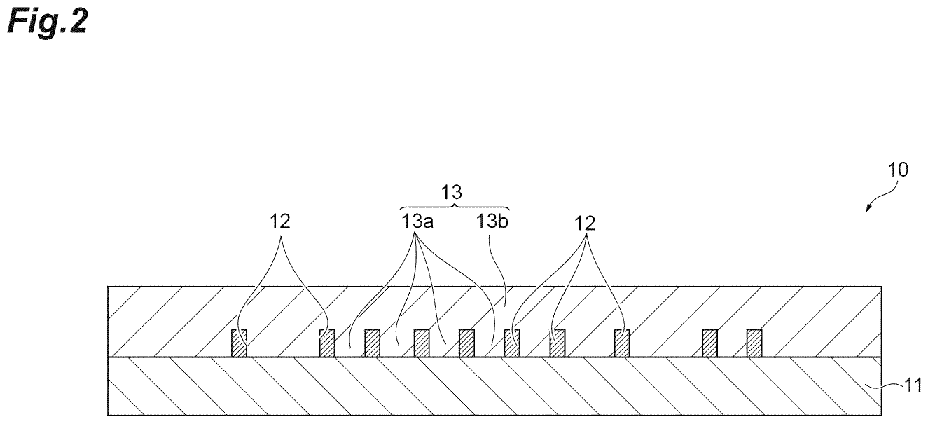

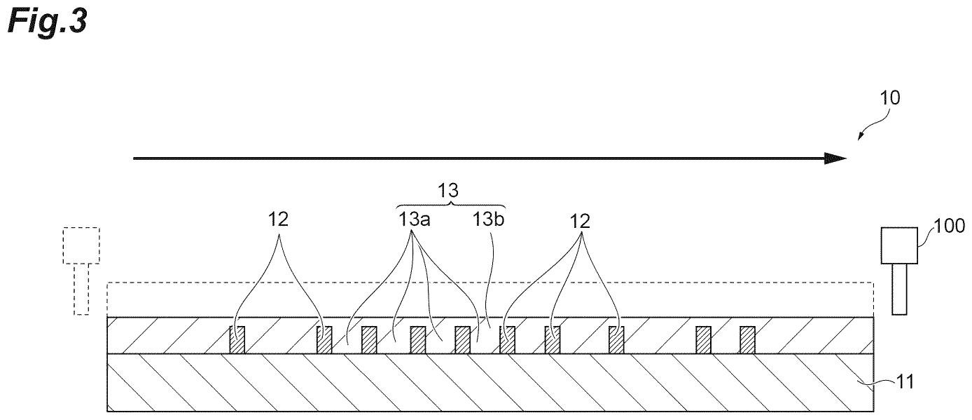

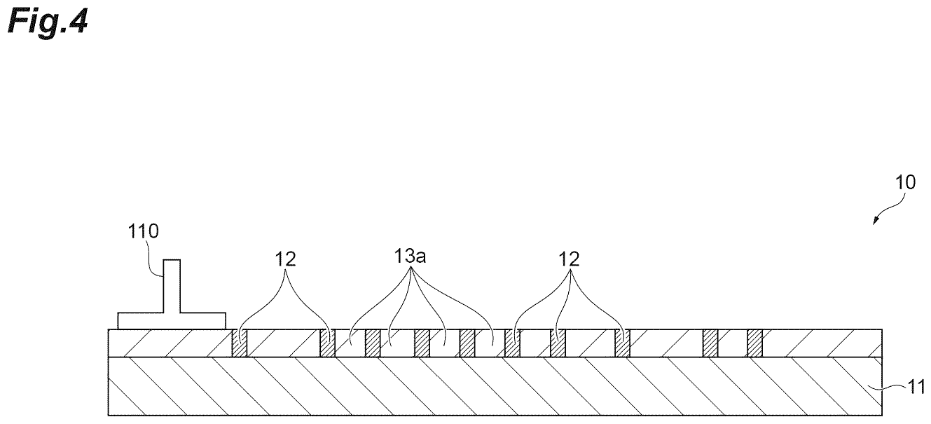

Next, a method for manufacturing the semiconductor device 1 will be described with reference to FIGS. 2 to 5. FIG. 2 is a cross-sectional view for explaining the method for manufacturing a semiconductor device according to the present embodiment, showing an example of a step of preparing a substrate. FIG. 3 is a cross-sectional view for explaining the method for manufacturing a semiconductor device according to the present embodiment, showing an example of a step of cutting a second portion of an insulating film by a fly-cutting method. FIG. 4 is a cross-sectional view for explaining the method for manufacturing a semiconductor device according to the present embodiment, showing an example of a step of polishing a surface of the cut insulating film. FIG. 5 is a cross-sectional view for explaining the method for manufacturing a semiconductor device according to the present embodiment, showing an example of a step of bonding a substrate and another substrate.

The semiconductor device 1 can be manufactured, for example, through the following steps (a) to (g). That is, the method for manufacturing the semiconductor device 1 includes the following steps (a) to (g).
a) A preparing step of preparing a substrate, the substrate including: a support substrate; a conductive part provided on the support substrate; and an insulating film provided on the support substrate and on the conductive part, wherein the insulating film includes: a first portion covering a surface of the support substrate and a side surface of the conductive part; and a second portion positioned on the first portion and covering a top surface of the conductive part.
b) A cutting step of cutting at least a portion of the second portion by a fly-cutting method while leaving the first portion.
c) A polishing step of polishing a surface of the insulating film, which is performed after step (b).
d) A preparing step of preparing a substrate, the substrate including: another support substrate; another conductive part provided on the another support substrate; and another insulating film provided on the another support substrate and on the another conductive part and a bonding step of bonding the substrate and the another substrate after the polishing step, wherein the another insulating film includes: another first portion covering a surface of the support substrate and a side surface of the conductive part; and another second portion positioned on the first portion and covering a top surface of the conductive part.
e) A cutting step of cutting at least a portion of the another second portion by a fly-cutting method while leaving the another first portion.
f) A polishing step of polishing a surface of the another insulating film, which is performed after step (e).
g) A bonding step of bonding the substrate and the another substrate, which is performed after step (c) and step (f).

Further, the step g) of bonding the substrate and the another substrate includes the following steps.
g1) A bonding step of bonding the insulating film of the substrate and the another insulating film of the another substrate.
g2) A bonding step of bonding the conductive part of the substrate and the another conductive part of the another substrate.
   [Step (a)]

Step (a) is a step of preparing the substrate 10. To prepare the substrate 10, first, a support substrate 11 including a conductive part 12 and an insulating film 13 is prepared. For example, the support substrate 11 is a silicon wafer. The support substrate 11 is, for example, a silicon wafer with a thickness of 0.2 mm or more and 2.0 mm or less. The diameter of the support substrate 11 is, for example, 200 mm, 300 mm, or 450 mm. Alternatively, the support substrate 11 may be a substrate including a glass plate, a SUS plate, or a glass cloth plate, or may be a resin substrate for sealing a semiconductor element. The support substrate 11 may be a panel-shaped substrate. In this case, the support substrate 11 is, for example, a rectangular panel with one side of 300 mm or more and 700 mm or less. The support substrate 11 may have other configurations.

In the substrate 10 prepared in step (a), the conductive part 12 is provided on the support substrate 11. Such a conductive part 12 is provided on the support substrate 11 using, for example, a photosensitive material. In this case, the conductive part 12 is provided on the support substrate 11, for example, as follows. First, an underlying layer is provided on the support substrate 11. This underlying layer is a portion that becomes a seed during electrolytic plating described later. Next, a resist layer is provided on the underlying layer. In one example, a film-like insulating material is attached as the resist layer onto the support substrate 11 by a lamination process.

This lamination process is performed, for example, by setting the temperature to 40° C. or more and 120° C. or less. For this reason, it is preferable to use a photosensitive insulating film that can be laminated at 40° C. or more and 120° C. or less as the film-like insulating material. By setting the laminatable temperature to 40° C. or more, it is possible to suppress the tack (adhesiveness) of the photosensitive insulating film from becoming strong at room temperature and to maintain good handleability of the photosensitive insulating film. By setting the laminatable temperature of the photosensitive insulating film to 120° C. or less, it is possible to suppress the occurrence of warpage in the photosensitive insulating film after the lamination process. Note that “room temperature” indicates about 25° C.

Next, an opening is provided in the resist layer by performing exposure and development on the resist layer. In the present embodiment, a plurality of openings are provided in the resist layer corresponding to the plurality of electrodes 2. Specifically, a pattern corresponding to the conductive part 12 is formed by performing predetermined exposure with a photomask placed on the resist layer. Then, the exposed resist layer is developed using a developer. As a result, the unexposed portions of the resist layer are dissolved, and a plurality of openings are formed. At this time, the underlying layer is exposed within the plurality of openings.

Next, the conductive part 12 is provided such that at least a portion thereof is positioned within the plurality of openings. In one example, the conductive part 12 is formed by electrolytic plating using the underlying layer exposed in the plurality of openings as a seed layer. The conductive part 12 is formed so as to be positioned at least partially within the plurality of openings. In this case, for example, the plurality of openings are filled by copper plating, and the conductive part 12 is formed.

Next, the resist layer is stripped from the support substrate 11. The stripping is performed using a commonly used stripping solution.

The conductive part 12 provided by the above method includes, for example, a copper pillar having a diameter of 0.5 μm or more and 20 μm or less. The volume resistivity of the conductive part 14 is, for example, 40 μΩ·cm or less from the viewpoint of transmission efficiency. From the viewpoint of suppressing heat generation, the volume resistivity is preferably 30 μΩ·cm or less. From the viewpoint of reliability, the volume resistivity is more preferably 20 μΩ·cm or less. Note that the volume resistivity is usually 3 μΩ·cm or more.

In the substrate 10 prepared in step (a), the insulating film 13 is provided on the support substrate 11 and on the conductive part 12. Such an insulating film 13 is provided, for example, by applying a liquid organic insulating material onto the surface of the support substrate 11 and the surface of the conductive part 12 by spin coating.

The organic insulating material is, for example, polyimide, a polyimide precursor, polyamide-imide, benzocyclobutene (BCB), polybenzoxazole (PBO), or a PBO precursor.

Furthermore, in the substrate 10 prepared in step (a), the insulating film 13 includes a first portion 13a and a second portion 13b. The first portion 13a covers a surface of the support substrate 11 and a side surface of the conductive part 12. The second portion 13b is positioned on the first portion 13a and covers a top surface of the conductive part 12. The thickness of the second portion 13b is, for example, 1 μm or more and 20 μm or less. The first portion 13a and the second portion 13b are provided integrally.

A thickness of the insulating film 13 formed on the support substrate 11 is, for example, 10 μm or less, preferably 5 μm or less, and more preferably 3 μm or less. The thickness of the insulating film 13 may be 1 μm or more. The thickness of the insulating film 13 is, for example, a total thickness of the first portion 13a and the second portion 13b. Note that the insulating film 13 may be formed from an inorganic material.

After providing the insulating film 13, the insulating film 13 may be heat-cured. In this case, the heating temperature may be, for example, 100° C. or more and 400° C. or less, and the heating time may be set to, for example, 30 minutes or more and 3 hours or less.

Through the above step (a), as shown in FIG. 2, a substrate is prepared that includes the support substrate 11, the conductive part 12 provided on the support substrate 11, and the insulating film 13 provided on the support substrate 11 and on the conductive part 12. Therefore, it can also be said that step (a) includes a step of providing an underlying layer on the support substrate 11, a step of providing a resist layer on the underlying layer, a step of providing an opening in the resist layer by performing exposure and development on the resist layer, a step of providing the conductive part 12 such that at least a portion thereof is positioned within the opening, and a step of providing the insulating film 13 on the support substrate 11 and on the conductive part 12.

[Step (b)]

Step (b) is a step of cutting the insulating film 13. In step (b), the insulating film 13 is cut by a fly-cutting method. In one example, while leaving the first portion 13a of the insulating film 13 that covers the surface of the support substrate 11 and the side surface of the conductive part 12, the second portion 13b that covers the top surface of the conductive part 12 is cut by the fly-cutting method.

In step (b) in the present embodiment, as shown in FIG. 3, the second portion 13b is cut by the fly-cutting method such that a surface of the second portion 13b protrudes from the top surface of the conductive part 12 (such that a part of the second portion 13b remains). That is, in step (b) in the present embodiment, the thickness of the second portion 13b is reduced by the fly-cutting method. Therefore, it can also be said that in step (b) in the present embodiment, a part of the second portion 13b is removed by cutting. A thickness of the second portion 13b to be cut by the fly-cutting method is, for example, 0.5 μm or more and 20 μm or less. Therefore, at the time when step (b) in the present embodiment is completed, the thickness of the second portion 13b is, for example, 3.0 μm or more and 10 μm or less.

In the fly-cutting method, for example, a grinding apparatus 100 with a diamond tool is used. In this case, as shown in FIG. 3, the second portion 13b is cut by moving the grinding apparatus 100 in a predetermined direction on the substrate 10. As a specific example of the grinding apparatus 100, an automatic surface planer compatible with 300 mm wafers (product name “DAS8930” manufactured by DISCO CORPORATION) can be used. Note that the cutting of the second portion 13b by the fly-cutting method can also be referred to as a planarization process. In step (b), etching or the like may be combined with the fly-cutting method.

At the time when step (b) in the present embodiment is completed, a surface roughness of the second portion 13b cut by the fly-cutting method is, for example, 10 nm or more and 100 nm or less. The surface roughness in the present embodiment is the arithmetic mean roughness (Ra) defined in JIS B 0601:2001. The surface roughness of the second portion 13b after cutting is measured, for example, by scanning a 100 μm×100 μm area including the second portion 13b using a laser microscope (“LEXT OLS3000” manufactured by Olympus Corporation).

[Step (c)]

Step (c) is a step of polishing the surface of the insulating film 13, and is a step performed after the grinding of step (b). In step (c) in the present embodiment, as shown in FIG. 4, a remaining portion of the cut second portion 13b is polished such that the surface of the first portion 13a and the top surface of the conductive part 12 are flush with each other. More specifically, by polishing the surface of the remaining portion of the cut second portion 13b, the second portion 13b remaining after step (b) is removed, and the surface of the first portion 13a and the top surface of the conductive part 12 are made flush with each other. In step (c) in the present embodiment, after making the surface of the first portion 13a and the top surface of the conductive part 12 flush with each other, the surface of the first portion 13a and the top surface of the conductive part 12 are further polished.

For the above-mentioned polishing, a method such as a grinder for processing electronic materials or a CMP (Chemical Mechanical Polishing) method can be used. In step (c) in the present embodiment, the surface of the second portion 13b is polished by the CMP method. In the CMP method, for example, a polishing apparatus 110 is used. In this case, as shown in FIG. 4, by rotating the polishing apparatus 110 while pressing it against the surface of the second portion 13b, the surface of the second portion 13b is polished by mechanical friction between the polishing liquid applied to the surface of the polishing apparatus 110 and the second portion 13b. Note that the polishing of the surface of the second portion 13b by the CMP method can also be referred to as a planarization process.

At the time when step (c) in the present embodiment is completed, a surface roughness of the first portion 13a is, for example, 0.5 nm or more and 3.0 nm or less due to the above-mentioned polishing. A surface roughness of the top surface of the conductive part 12 is, for example, 0.5 nm or more and 3.0 nm or less. The surface roughness is the arithmetic mean roughness (Ra) defined in JIS B 0601:2001. The surface roughness of the first portion 13a and the surface roughness of the top surface of the conductive part 12 after polishing are measured, for example, by a method similar to that for the surface roughness of the second portion 13b after cutting.

[Step (d)]

Step (d) is a step of preparing another substrate 20, which is different from the substrate 10. In step (d), a substrate 20 is prepared that includes a support substrate 21, a conductive part 22 provided on the support substrate 21, and an insulating film 23 provided on the support substrate 21 and on the conductive part 22. In the substrate 20 prepared in step (d), the insulating film 23 includes a first portion 23a covering a surface of the support substrate 21 and a side surface of the conductive part 22, and a second portion 23b positioned on the first portion 23a and covering a top surface of the conductive part 22. Since the method for preparing the substrate 20 is the same as the method for preparing the substrate 10, a detailed description is omitted, but the substrate 20 is prepared through the steps described above. The substrate 20 does not need to have a completely identical configuration to the substrate 10, and a thickness or forming material of the support substrate 21, a thickness or forming material of the insulating film 23, and the like may be different from those of the substrate 10.

[Step (e)]

Step (e) is a step of cutting the second portion 23b. Since the method for cutting the second portion 23b is the same as the method for cutting the second portion 13b, a detailed description is omitted, but the second portion 23b is cut through the step shown in FIG. 3. In step (e), the second portion 23b may be cut such that a surface of the second portion 23b protrudes from the top surface of the conductive part 22.

[Step (f)]

Step (f) is a step of polishing a surface of the insulating film 23, and is a step performed after step (e). Since the method for polishing the surface of the insulating film 23 is the same as the method for polishing the surface of the insulating film 13, a detailed description is omitted, but the surface of the insulating film 23 is cut through the step shown in FIG. 4. In step (f), the surface of the second portion 23b may be polished such that a surface of the first portion 23a and the top surface of the conductive part 22 are flush with each other.

[Step (g)]

Step (g) is a step of bonding the substrate 10 and the substrate 20, and is a step performed after step (c) and step (f). In step (g), first, the insulating film 13 of the substrate 10 and the insulating film 23 of the substrate 20 are bonded. Here, alignment of at least one of the substrate 10 and the substrate 20 is performed so that the conductive part 12 of the substrate 10 and the conductive part 22 of the substrate 20 oppose each other. Alignment of both the substrate 10 and the substrate 20 may be performed. For such alignment, alignment marks or the like may be provided on at least one of the substrate 10 and the substrate 20.

When bonding the substrate 10 and the substrate 20, after removing organic substances or metal oxides adhering to the surfaces of the substrate 10 and the substrate 20, the substrate 20 is aligned with respect to the substrate 10. Then, when the alignment is completed, the first portion 13a of the insulating film 13 and the first portion 23a of the insulating film 23 are bonded as hybrid bonding. At this time, the first portion 13a and the first portion 23a may be bonded after being uniformly heated. By bonding the first portion 13a and the first portion 23a, the insulating film 3 of the semiconductor device 1 is formed as shown in FIG. 1.

A temperature difference between the substrate 10 and the substrate 20 during bonding is preferably 10° C. or less, for example. By such heat bonding at a uniform temperature, the insulating film 13 is mechanically and strongly attached to the insulating film 23. In addition, since it is heat bonding at the uniform temperature, positional deviation or the like at the bonding location is unlikely to occur, and high-precision bonding can be performed. Note that the bonding of the substrate 10 and the substrate 20 may be performed by other bonding methods, for example, by room temperature bonding or the like.

Next, when the bonding of the insulating film 13 of the substrate 10 and the insulating film 13 of the substrate 20 is completed, the conductive part 12 of the substrate 10 and the conductive part 22 of the substrate 20 are bonded. In the present embodiment, as shown in FIG. 5, when the bonding of the insulating film 13 and the insulating film 23 is completed, the conductive part 12 and the conductive part 22 are bonded as hybrid bonding by applying predetermined heat or pressure, or both. In a configuration in which the conductive part 12 and the conductive part 22 are formed from copper, the annealing temperature here is preferably 150° C. or more and 400° C. or less, and more preferably 200° C. or more and 300° C. or less. By such a bonding process, the conductive part 12 and the conductive part 22 become the bonded electrode 2, and the electrode 2 in which the conductive part 12 and the conductive part 22 are mechanically and electrically strongly bonded is formed. Note that the electrode bonding may be performed after the bonding of the insulating film 13 and the insulating film 23, or may be performed simultaneously with the bonding of the insulating film 13 and the insulating film 23.

Through the above steps, the semiconductor device 1 shown in FIG. 1 is manufactured.

As described above, according to the method for manufacturing the semiconductor device 1 of the present embodiment, in step (b), after cutting the part (a large part) of the second portion 13b covering the top surface of the conductive part 12 by the fly-cutting method while leaving the first portion 13a covering the surface of the support substrate 11 and the side surface of the conductive part 12, the surface of the insulating film 13 is polished. In this case, a part of step (c) can be replaced by step (b). This makes it possible to reduce the surface roughness while shortening the operation time in step (c). Therefore, according to the method for manufacturing the semiconductor device 1, the surface roughness can be easily reduced.

When planarizing the substrate surface, the conductive part 12 that becomes the electrode 2 may be elongated, and a shape of the conductive part 12 may change. If the shape of the conductive part 12 changes, there is a risk of bonding failure during hybrid bonding. In the method for manufacturing the semiconductor device 1, in step (b), the second portion 13b is cut such that at least the part of the second portion 13b remains. In step (c), the surface of the second portion 13b is polished such that the surface of the first portion 13a and the top surface of the conductive part 12 are flush with each other. According to the method for manufacturing the semiconductor device 1, a change in the shape of the conductive part 12 can be suppressed, and bonding failure during subsequent hybrid bonding can be suppressed.

In the method for manufacturing the semiconductor device 1, in step (c), the surface of the ground insulating film 13 is polished by the CMP method. According to the method for manufacturing the semiconductor device 1, step (c) can be performed easily. In addition, the surface roughness of the surface of the insulating film 13 can be more reliably reduced.

The method for manufacturing the semiconductor device 1 includes step (d) of preparing the substrate 20 including the support substrate 21, the conductive part 22 provided on the support substrate 21, and the insulating film 23 provided on the support substrate 21 and on the conductive part 22, and step (g) of bonding the substrate 10 and the substrate 20 after step (d). In this case, for the reasons described above, the substrate 10 and the substrate 20 are bonded in a state where the surface roughness of the substrate 10 is reduced. Therefore, according to the method for manufacturing the semiconductor device 1, the bonding strength between the substrate 10 and the substrate 20 can be improved.

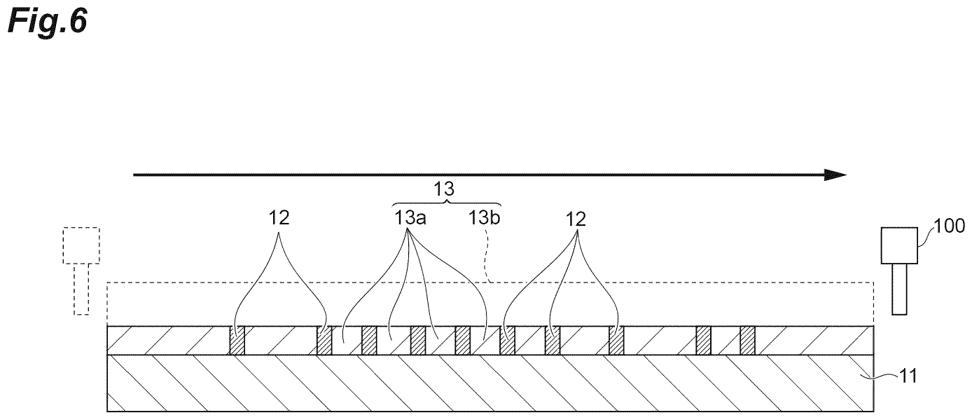

Next, a modification of the method for manufacturing the semiconductor device 1 will be described with reference to FIG. 6. FIG. 6 is a cross-sectional view for explaining a modification of the method for manufacturing a semiconductor device according to the present embodiment, showing another example of the step of cutting the second portion of the insulating film by the fly-cutting method.

In this modification, as shown in FIG. 6, in step (b), the second portion 13b is cut by the fly-cutting method such that the surface of the first portion 13a and the top surface of the conductive part 12 are flush with each other. That is, it can also be said that in step (b) in this modification, the entire second portion 13b is removed by cutting by the fly-cutting method.

In the fly-cutting method, as in the above-described embodiment, for example, a grinding apparatus 100 with a diamond tool is used. In this case as well, as shown in FIG. 6, the second portion 13b is cut by moving the grinding apparatus 100 in the predetermined direction on the substrate 10.

At the time when step (b) in this modification is completed, the surface roughness of the first portion 13a, which has become flush with the top surface of the conductive part 12 by cutting by the fly-cutting method, is, for example, 10 nm or more and 100 nm or less. In this modification as well, the surface roughness is the arithmetic mean roughness (Ra) defined in JIS B 0601:2001. Also in this modification, the surface roughness of the first portion 13a after cutting is measured, for example, by scanning a 100 μm×100 μm area including the insulating film 13 using the laser microscope (“LEXT OLS3000” manufactured by Olympus Corporation).

As described above, in step (b) in this modification, the entire second portion 13b is removed by cutting by the fly-cutting method. Therefore, in step (c) in this modification, the surface of the first portion 13a is polished. In step (c) in this modification, in addition to the surface of the first portion 13a, the top surface of the conductive part 12 may be polished.

At the time when step (c) in this modification is completed, the surface roughness of the first portion 13a becomes, for example, 0.5 nm or more and 3.0 nm or less by the above-mentioned polishing. The surface roughness of the top surface of the conductive part 12 becomes, for example, 0.5 nm or more and 3.0 nm or less. The surface roughness is the arithmetic mean roughness (Ra) defined in JIS B 0601:2001. The surface roughness of the first portion 13a and the surface roughness of the top surface of the conductive part 12 after polishing are measured, for example, by a method similar to that for the surface roughness of the second portion 13b after cutting.

In this modification, in step (b), the second portion 13b is cut such that the surface of the first portion 13a and the top surface of the conductive part 12 are flush with each other. In this case, it becomes possible to reduce the surface roughness while further shortening the operation time in step (b). Therefore, according to this modification, the surface roughness can be reduced even more easily.

### EXAMPLES

Hereinafter, the present invention will be described more specifically with reference to Examples, but the present invention is not limited to these Examples.

### Example 1

As a counterpart to the substrate 10 in the above-described embodiment, a substrate was prepared that included a support substrate, a conductive part provided on the support substrate, and a polyimide film provided on the support substrate and on the conductive part. The conductive part was provided by electrolytic copper plating. In the prepared substrate, the polyimide film included a portion covering a surface of the support substrate and a side surface of the conductive part, and a portion positioned on that portion and covering a top surface of the conductive part. In the prepared substrate, the elastic modulus of the polyimide film was 2.55 (GPa).

Next, while leaving the portion of the polyimide film covering the surface of the support substrate and the side surface of the conductive part, that portion of the polyimide film was cut by the fly-cutting method such that at least a part of the portion of the polyimide film covering the top surface of the conductive part remained. Next, the surface of a remaining portion of the cut portion of the polyimide film was polished by the CMP method such that the surface of the polyimide film and the top surface of the conductive part were flush with each other.

Thereafter, using the laser microscope (“LEXT OLS3000” manufactured by Olympus Corporation), a 100 μm×100 μm area on the substrate surface was scanned to measure the surface roughness of the substrate (arithmetic mean roughness (Ra) defined in JIS B 0601:2001). The surface roughness of the substrate is the surface roughness of the substrate in a state where the surface of the polyimide film and the top surface of the conductive part are flush, and includes the surface roughness of the polyimide film and the surface roughness of the top surface of the conductive part in that state. In addition, with the polyimide film and the conductive part captured in the image field of view, an image of the substrate was acquired from a direction orthogonal to the thickness direction of the substrate, and it was inspected from the acquired image whether the conductive part was elongated. As a result, in Example 1, the surface roughness of the substrate was 1.5 nm, and no elongation of the conductive part was confirmed.

### Example 2

In Example 2, a substrate similar to that of Example 1 was prepared. Next, while leaving a portion of the polyimide film covering the surface of the support substrate and the side surface of the conductive part, the portion of the polyimide film covering the top surface of the conductive part was cut by the fly-cutting method such that the surface of the polyimide film and the top surface of the conductive part were flush with each other. Next, the surface of the cut polyimide film and the top surface of the conductive part were polished by the CMP method.

Thereafter, in the same manner as in Example 1, the surface roughness of the substrate was measured, and it was inspected whether the conductive part was elongated. As a result, in Example 2, the surface roughness of the substrate was 1.5 nm, and elongation of the conductive part was confirmed.

### Comparative Example 1

In Comparative Example 1, a substrate similar to that of Example 1 was prepared. Next, in the same manner as in Example 1, the portion of the polyimide film covering the top surface of the conductive part was cut. In Comparative Example 1, polishing of the surface of the polyimide film by the CMP method was not performed. That is, in Comparative Example 1, only cutting of the polyimide film by the fly-cutting method was performed.

Thereafter, in the same manner as in Example 1, the surface roughness of the substrate was measured, and it was inspected whether the conductive part was elongated. As a result, in Comparative Example 1, the surface roughness of the substrate was 133 nm, and elongation of the conductive part was confirmed.

### Comparative Example 2

In Comparative Example 2, a substrate similar to that of Example 1 was prepared. Next, while leaving the portion of the polyimide film covering the surface of the support substrate and the side surface of the conductive part, the portion of the polyimide film covering the top surface of the conductive part was polished by the CMP method such that the surface of the polyimide film and the top surface of the conductive part were flush with each other. In Comparative Example 2, cutting of the polyimide film by the fly-cutting method was not performed. That is, in Comparative Example 2, only polishing of the surface of the polyimide film by the CMP method was performed.

Thereafter, in the same manner as in Example 1, the surface roughness of the substrate was measured, and it was inspected whether the conductive part was elongated. As a result, in Comparative Example 2, the surface roughness of the substrate was 1.5 nm, and elongation of the conductive part was confirmed.

When performing general hybrid bonding, it is desirable that the surface roughness of the substrate be 10 nm or less. Therefore, in evaluating the surface roughness of the substrates of Examples 1 and 2 and Comparative Examples 1 and 2, a case where the surface roughness of the substrate was 10 nm or less was evaluated as “Good (A),” and a case where the surface roughness of the substrate was greater than 10 nm was evaluated as “Fail (F).”

In Example 1, since the surface roughness of the substrate was 1.5 nm, Example 1 was evaluated as “A.” In Example 2, since the surface roughness of the substrate was 1.5 nm, Example 2 was evaluated as “A.” In Comparative Example 1, since the surface roughness of the substrate was 133 nm, Comparative Example 1 was evaluated as “F.” In Comparative Example 2, since the surface roughness of the substrate was 1.5 nm, Comparative Example 2 was evaluated as “A.”

Table 1 below summarizes the results of Examples 1 and 2 and Comparative Examples 1 and 2.

TABLE 1

| | | | Comparative | Comparative |
|---|---|---|---|---|
| | Example 1 | Example 2 | Example 1 | Example 2 |
| Surface roughness | A | A | F | A |
| Elongation of | None | Present | Present | None |
| conductive part | | | | |

First, focusing on the surface roughness. As shown in Table 1, Examples 1 and 2, in which the surface of the polyimide film was polished by the CMP method after cutting the polyimide film by the fly-cutting method, and Comparative Example 2 were judged as “A” for surface roughness. On the other hand, Comparative Example 1, in which the surface of the conductive part was not polished by the CMP method, was judged as “F” for surface roughness. Therefore, it can be seen that when the surface of the polyimide film (insulating film) is polished by the CMP method after cutting the polyimide film (insulating film) by the fly-cutting method, the surface roughness of the substrate can be reduced.

Next, focusing on the elongation of the conductive part. As shown in Table 1, in Example 1, no elongation of the conductive part was confirmed. Therefore, it can be seen that in the step of cutting the polyimide film (insulating film), when that portion of the polyimide film is cut by the fly-cutting method such that at least the part of the portion of the polyimide film covering the top surface of the conductive part remains, elongation of the conductive part is suppressed, and a change in the shape of the conductive part can be prevented. As a result, it can be seen that in the step of cutting the polyimide film (insulating film), when that portion of the polyimide film is cut by the fly-cutting method such that at least the part of the portion of the polyimide film covering the top surface of the conductive part remains, bonding failure during hybrid bonding can be more reliably suppressed. Regarding Example 2, in which elongation of the conductive part was confirmed, it was considered possible to use it for hybrid bonding by, for example, removing the elongated portion of the conductive part before the step of bonding the substrate to another substrate.

Furthermore, when the surface roughness of the substrate is 10 nm or less and no elongation of the conductive part is confirmed, it is expected that the bondability during hybrid bonding will be good. Therefore, it is expected that in the step of cutting the polyimide film (insulating film), when that portion of the polyimide film is cut by the fly-cutting method such that at least the part of the portion of the polyimide film covering the top surface of the conductive part remains, the bondability during hybrid bonding can be made good.

When comparing the fly-cutting method and the CMP method, the thickness of the polyimide film (insulating film) removed per unit time by the fly-cutting method tends to be greater than the same thickness by the CMP method. Therefore, when removing the same thickness of the polyimide film, the time required for the fly-cutting method is expected to be shorter than the time required for the CMP method. That is, the processing time in Examples 1 and 2, in which polishing of the polyimide film by the CMP method was performed after cutting of the polyimide film by the fly-cutting method, is expected to be shorter than the processing time in Comparative Example 2, in which only polishing of the polyimide film by the CMP method was performed. Therefore, it is understood that by replacing a part of the step of polishing the polyimide film by the CMP method with the step of cutting the polyimide film by the fly-cutting method, the processing time in the polishing step can be shortened.

Although the embodiments of the present disclosure have been described above, the present invention is not limited to the above-described embodiments, and may be appropriately modified without departing from the spirit of the invention.

In the above embodiments, the conductive parts 12, 22 are formed by electrolytic plating, but the invention is not limited to this. For example, the conductive parts 12, 22 may be formed using at least one of sputtering and electroless plating. Alternatively, the conductive parts 12, 22 may be formed by combining at least one of sputtering, electroplating, and electroless plating with a copper paste application step and a sintering step.

### REFERENCE SIGNS LIST

10, 20 . . . substrate, 11, 21 . . . support substrate, 12, 22 . . . conductive part, 13, 23 . . . insulating film, 13a, 23a . . . first portion, 13b, 23b . . . second portion.

1. A method for manufacturing a semiconductor device, comprising:
preparing a substrate,
wherein the substrate comprises:
a support substrate;
a conductive part provided on the support substrate; and
an insulating film provided on the support substrate and on the conductive part, and
wherein the insulating film comprises:
a first portion covering a surface of the support substrate and a side surface of the conductive part; and
a second portion positioned on the first portion and covering a top surface of the conductive part;
cutting at least a portion of the second portion by a fly-cutting method while leaving the first portion; and
polishing a surface of the insulating film,
wherein the polishing is performed after the cutting.

2. The method for manufacturing a semiconductor device according to claim 1,
wherein, in the cutting, the second portion is cut such that at least a part of the second portion remains, and
wherein, in the polishing, a remaining portion of the cut second portion is polished such that a surface of the first portion and the top surface of the conductive part are flush with each other.

3. The method for manufacturing a semiconductor device according to claim 1,
wherein, in the cutting, the second portion is cut such that a surface of the first portion and the top surface of the conductive part are flush with each other, and
wherein, in the polishing, the surface of the first portion is polished.

4. The method for manufacturing a semiconductor device according to claim 1,
wherein in the polishing, a surface of the cut insulating film is polished by a CMP method.

5. The method for manufacturing a semiconductor device according to claim 1, further comprising:
preparing a substrate,
wherein, the substrate comprises:
another support substrate;
another conductive part provided on the another support substrate; and
another insulating film provided on the another support substrate and on the another conductive part; and
bonding the substrate and the another substrate after the polishing.
